(19) United States
(12) Patent Application Publication
(10) Pub. No.: US 2022/0139977 A1
(43) Pub. Date: May 5, 2022

(54) STREAKING-FREE CMOS IMAGE SENSOR WITH ON-GATE DUAL-ELECTRODE PASS TRANSISTOR

(71) Applicant: TIANJIN UNIVERSITY, Tianjin (CN)

(72) Inventors: Jiangtao Xu, Tianjin (CN); Yu Zhang, Tianjin (CN); Kaiming Nie, Tianjin (CN); Jing Gao, Tianjin (CN)

(21) Appl. No.: 17/338,652

(22) Filed: Jun. 3, 2021

(30) Foreign Application Priority Data
Oct. 30, 2020 (CN) 2020111921903

(51) Int. Cl. H01L 27/146

(52) U.S. Cl. CPC H01L 27/14612; H01L 27/14603; H01L 27/14643

(57) ABSTRACT

A streaking-free CMOS image sensor with an on-gate dual-electrode pass transistor is provided, including a silicon substrate, clamping photodiodes arranged in a photosensitive region, a dual-electrode charge transfer gate, namely a pass transistor, a charge-to-voltage conversion node, and a reset transistor, wherein the photoelectric conversion region of the clamping photodiode is located on a left side of the pass transistor and directly connected to a channel below a gate of the pass transistor, and a right side of the pass transistor is tightly connected to the charge-to-voltage conversion node. The present invention changes the potential of a charge transfer channel through a sequential coordination of applying different voltages to a gate of the pass transistor by double electrodes, thus achieving fast charge transfer and readout while reducing streaking.

### CROSS-REFERENCE TO RELATED APPLICATION

This application claims priority from the Chinese patent application 2020111921903 filed Oct. 30, 2020, the content of which is incorporated herein in the entirety by reference.

### TECHNICAL FIELD

The present invention belongs to the field of image sensors, and particularly relates to a streaking-free CMOS image sensor with an on-gate dual-electrode pass transistor.

### BACKGROUND OF THE PRESENT INVENTION

With the advantages of low power consumption, high sensitivity, wide dynamic range and high integration, CMOS image sensors are gradually widely used in fields such as smart phones, medical examinations, security monitoring and aerospace to replace CCD image sensor. With the development of integrated circuit technology, the demand for high-performance CMOS image sensors is growing dramatically. However, with the increase of operating frequency of CMOS image sensor chips and the increase of pixel array scale, the problems of slower charge transfer rate and streaking in a charge transfer channel gradually emerge. Conventional CMOS image sensors convert photons into electrons based on the photoelectric conversion principle of clamping photodiodes, and the electrons are transferred to a charge-to-voltage conversion node through the charge transfer channel below a pass transistor and integrated into voltage. Due to the volatility of the technology, a potential well which will cause streaking was designed in front of the charge transfer channel in order to achieve fast charge transfer readout. If a gate of the pass transistor is made into double electrodes, the potential of the charge transfer channel can be effectively changed through voltage matching of the double electrodes without changing the doping and morphology of a pixel active region, thus achieving fast charge transfer readout while reducing streaking.

### SUMMARY OF THE PRESENT INVENTION

In order to overcome the shortcomings of the prior art, the present invention aims to propose a streaking-free CMOS image sensor with an on-gate dual-electrode pass transistor, without changing the doping and morphology of a pixel active region, the present invention changes the potential of a charge transfer channel through a sequential coordination of applying different voltages to a gate of the pass transistor by double electrodes, thus achieving fast charge transfer and readout while reducing streaking. To this end, a technical solution employed in the present application is that a streaking-free CMOS image sensor with an on-gate dual-electrode pass transistor is provided, including a silicon substrate, clamping photodiodes arranged in a photosensitive region, a dual-electrode charge transfer gate, namely a pass transistor, a charge-to-voltage conversion node, and a reset transistor, wherein the photoelectric conversion region of the clamping photodiode is located on a left side of the pass transistor and directly connected to a channel below a gate of the pass transistor, and a right side of the pass transistor is tightly connected to the charge-to-voltage conversion node.

The sensor operates in three processes, namely reset, exposure and charge transfer:
at the beginning of reset, a gate of the reset transistor and the gate of the pass transistor are simultaneously connected to a supply voltage and powered on, and charges in the photoelectric conversion region finally enter the reset transistor through a charge transfer channel; at the end of reset, the gates of the pass transistor and the reset transistor are grounded in turn, a reset voltage is stored at the charge-to-voltage conversion node, wherein the gate of the pass transistor is grounded first;
in the process of exposure, the gates of the reset transistor and the pass transistor are grounded and powered off, the photoelectric conversion region of the clamping photodiode converts input photons into electrons according to the photoelectric effect and stores the converted electrons; during the process of the photoelectric conversion, the potential in the region gradually decreases, and the reduced voltage is an optical signal; and
in the process of charge transfer, optical signal charges reach the charge-to-voltage conversion node through the charge transfer channel and are converted into an optical signal voltage, the left side of the gate of the pass transistor is connected to a pulse voltage and a right side thereof is connected to the supply voltage, wherein a high-level pulse voltage is slightly higher than the supply voltage while a low-level pulse voltage is slightly lower than the supply voltage, and the gate of the reset transistor is grounded and powered off; a small charge potential well is positioned below the gate of the pass transistor close to a P-type clamping layer of the clamping photodiode for fast charge readout; the thermionic emission theory shows that the potential difference in this potential well region is more variable and therefore a forward current is larger, but the potential of electrons in the center of the potential well acts as a potential barrier relative to the potential at the edge of the potential well, which will reduce the emission current in the second half of the process. On the premise of ensuring a smooth rise in the potential of an electron transfer channel in the second half of the process, a pulse voltage is applied by an electrode on the left side of the gate of the pass transistor, and a high-level pulse voltage is equivalent to increasing the depth of the potential well, allowing charges in the clamping photodiode to be extracted faster; when the potential well is almost filled with electrons, the pulse voltage changes to a low-level pulse voltage, which is equivalent to reducing the potential of electrons in the potential well. In this way, the potential of electrons in the center of the potential well is reduced relative to the potential barrier at the edge of the potential well, and electrons are smoothly transferred to the smooth charge transfer channel in the second half of the process, thus achieving fast charge readout and eliminating streaking.

The present invention has following characteristics and beneficial effects.

The streaking-free CMOS image sensor with the on-gate dual-electrode pass transistor proposed in the present invention can, without changing the doping and morphology of the pixel active region, achieve fast charge readout and eliminate streaking by controlling the gate voltage of the pass transistor. Compared with the traditional method of eliminating streaking of CMOS image sensors, the present invention is more flexible and easy to implement.

### BRIEF DESCRIPTION OF THE DRAWINGS

FIG. 1 is a schematic diagram of a pixel active region of a dual-electrode CMOS image sensor, where
References 1, 2 constitute a gate of a pass transistor;
when starting the pass transistor, the reference 1 is applied a pulse voltage while the reference 2 is applied a supply voltage;
references 3, 4 constitute a clamping photodiode;
wherein the reference 3 is a surface P-type clamping layer while the reference 4 is a photoelectric conversion region;
reference 5 is a charge-to-voltage conversion node equivalent to a source of a reset transistor;
reference 6 is substrate grounding;
reference 7 is a gate of the reset transistor;
reference 8 is a drain of the reset transistor connected to the supply voltage;

FIG. 2 is a schematic diagram of streaking generation;

FIG. 3 is an operating sequence chart; and

FIG. 4 is a charge transfer potential pattern.

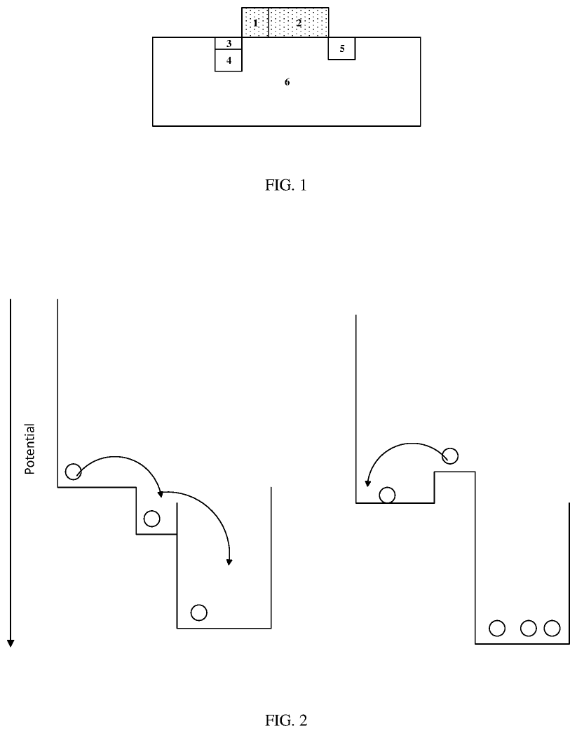

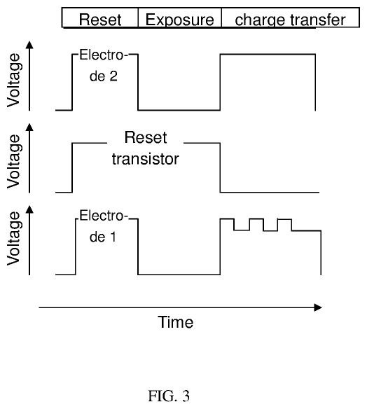

### DETAILED DESCRIPTION OF THE PRESENT INVENTION

The present invention proposes a streaking-free CMOS image sensor with an on-gate dual-electrode pass transistor, including a silicon substrate, clamping photodiodes arranged in a photosensitive region, a dual-electrode charge transfer gate, a charge-to-voltage conversion node, and a reset transistor. The photoelectric conversion region of the clamping photodiode is located on a left side of the pass transistor and directly connected to a channel below a gate of the pass transistor, and a right side of the pass transistor is tightly connected to the charge-to-voltage conversion node. The above structure constitutes a charge transfer channel consisting of “the photoelectric conversion region, a channel on a lower surface of the gate of the pass transistor, and the charge-to-voltage conversion node”.

An operating process of the dual-electrode transfer gate CMOS image sensor includes three processes, namely reset, exposure and charge transfer. At the beginning of reset, a gate of the reset transistor and the gate of the pass transistor are simultaneously connected to a supply voltage and powered on, and charges in the photoelectric conversion region finally enter the reset transistor through the charge transfer channel. At the end of reset, the gates of the pass transistor and the reset transistor are grounded in turn, and a reset voltage is stored at the charge-to-voltage conversion node. Wherein, grounding the gate of the pass transistor first is to reduce the coupling capacitance of the device so as to obtain a higher reset voltage. According to the thermionic emission theory, the charge transfer rate is positively correlated with the potential difference. The charge transfer channel herein shows that the charge transfer rate is positively correlated with the potential difference between the photoelectric conversion region and the charge-to-voltage conversion node, so a higher charge transfer rate can be obtained by such reset sequence.

In the process of exposure, the gates of the reset transistor and the pass transistor are grounded and powered off, the photoelectric conversion region of the clamping photodiode converts input photons into electrons according to the photoelectric effect and stores the converted electrons. During the process of the photoelectric conversion, the potential in the region gradually decreases, and the reduced voltage is an optical signal.

In the process of charge transfer, optical signal charges reach the charge-to-voltage conversion node through the charge transfer channel and are converted into an optical signal voltage. A left side of the gate of the pass transistor is connected to a pulse voltage and a right side thereof is connected to the supply voltage, wherein a high-level pulse voltage is slightly higher than the supply voltage while a low-level pulse voltage is slightly lower than the supply voltage, and the gate of the reset transistor is grounded and powered off. A small charge potential well is positioned below the gate of the pass transistor close to a P-type clamping layer of the clamping photodiode for fast charge readout. According to the thermionic emission theory, the potential difference in this potential well region is more variable and therefore a forward current is larger, but the potential of electrons in the center of the potential well acts as a potential barrier relative to the potential at the edge of the potential well, which will reduce the emission current in the second half of the process. On the premise of ensuring a smooth rise in the potential of an electron transfer channel in the second half of the process, a pulse voltage is applied by an electrode on the left side of the gate of the pass transistor, and a high-level pulse voltage is equivalent to increasing the depth of the potential well, allowing charges in the clamping photodiode to be extracted faster. When the potential well is almost filled with electrons, the pulse voltage changes to a low-level pulse voltage, which is equivalent to reducing the potential of electrons in the potential well. In this way, the potential of electrons in the center of the potential well is reduced relative to the potential barrier at the edge of the potential well, and electrons are smoothly transferred to the smooth charge transfer channel in the second half of the process, thus achieving fast charge readout and eliminating streaking.

The present invention is additionally fitted with double electrodes into the gate of the transmission tube on the basis of the existing four-tube active pixel CMOS image sensor, and adjust the potential of the charge transfer channel through a sequential coordination of applying different voltages to the pass transistor to achieve fast charge transfer and readout while reducing streaking.

A streaking-free CMOS image sensor with an on-gate dual-electrode pass transistor is further provided, including a silicon substrate, a photosensitive region consisting of clamping photodiodes, a dual-electrode transfer gate, a charge-to-voltage conversion node, and a reset transistor. When the sensor starts to operate, the double electrodes on the pass transistor are simultaneously connected to a supply voltage. At this moment, the power supply extracts charges from a space charge layer of the clamping photodiode to empty this layer. In a process of exposure, since an absorption depth corresponding to the wavelength of visible light is just located in the space charge layer of the clamping photodiode, photons realize the photoelectric conversion in this layer. As the photoelectric conversion proceeds, electrons are stored in the space charge layer and the potential thereof gradually decreases to a certain value. After exposure, the pass transistor is turned on. At this moment, the voltage of a left electrode is connected to a pulse voltage, wherein a high-level pulse voltage is equal to the supply voltage while a low-level pulse voltage is slightly lower than the supply voltage. A right electrode is connected to the supply voltage, the voltage value may be determined according to the actual needs.

When the left electrode is at the high-level pulse voltage, the charges are transferred from a clamping photodiode region to a potential well region. When the potential well is full of charges, the left electrode changes to be at the low-level pulse voltage, at which moment the potential well gradually disappears, and the charges in the potential well are forced to be transferred to a right charge transfer channel. A right electrode holds the supply voltage to ensure the normal opening of the right channel, so that the charges are transferred fast and repeatedly. When the charges are almost completely transferred, the left electrode continues to apply the low-level pulse voltage to ensure that no charge in left in the potential well, thus eliminating streaking.

1. A streaking-free CMOS image sensor with an on-gate dual-electrode pass transistor, comprising a silicon substrate, clamping photodiodes arranged in a photosensitive region, a dual-electrode charge transfer gate, namely a pass transistor, a charge-to-voltage conversion node, and a reset transistor;
wherein the photoelectric conversion region of the clamping photodiode being located on a left side of the pass transistor and directly connected to a channel below a gate of the pass transistor, and a right side of the pass transistor being tightly connected to a charge-to-voltage conversion node.

2. The streaking-free CMOS image sensor with an on-gate dual-electrode pass transistor according to claim 1, wherein the sensor operates in three processes, namely reset, exposure and charge transfer:
at the beginning of reset, a gate of the reset transistor and the gate of the pass transistor being simultaneously connected to a supply voltage and powered on, and charges in the photoelectric conversion region finally entering the reset transistor through a charge transfer channel; at the end of reset, the gates of the pass transistor and the reset transistor being grounded in sequence, a reset voltage being stored at the charge-to-voltage conversion node, and the gate of the pass transistor being grounded first;
in the process of exposure, the gates of the reset transistor and the pass transistor being grounded and powered off, the photoelectric conversion region of the clamping photodiode converting input photons into electrons according to photoelectric effect and storing the converted electrons; during the process of photoelectric conversion, the potential in the region gradually decreasing, and the reduced voltage being an optical signal; and
in the process of charge transfer, optical signal charges reaching the charge-to-voltage conversion node through the charge transfer channel and being converted into an optical signal voltage, a left side of the gate of the pass transistor being connected to a pulse voltage and a right side thereof being connected to the supply voltage;
wherein a high-level pulse voltage is slightly higher than the supply voltage while a low-level pulse voltage is slightly lower than the supply voltage, and the gate of the reset transistor is grounded and powered off; a small charge potential well is positioned below the gate of the pass transistor close to a P-type clamping layer of the clamping photodiode for fast charge readout; according to the thermionic emission theory, the potential difference in this potential well region is more variable and therefore a forward current is larger, but the potential of electrons in the center of the potential well acts as a potential barrier relative to the potential at the edge of the potential well, which will reduce an emission current in the second half of the process; on the premise of ensuring a smooth rise in the potential of an electron transfer channel in the second half of the process, a pulse voltage is applied by an electrode on the left side of the gate of the pass transistor, and a high-level pulse voltage is equivalent to increasing the depth of the potential well, allowing charges in the clamping photodiode to be extracted faster; when the potential well is almost filled with electrons, the pulse voltage changes to a low-level pulse voltage, which is equivalent to reducing the potential of electrons in the potential well; in this way, the potential of electrons in the center of the potential well is reduced relative to the potential barrier at the edge of the potential well, and electrons are smoothly transferred to the smooth charge transfer channel in the second half of the process, thus achieving fast charge readout and eliminating streaking.
